(19) United States
(12) Patent Application Publication
(10) Pub. No.: US 2019/0150260 A1
(43) Pub. Date: May 16, 2019

(54) DROPLET DETECTOR AND EUV LIGHT GENERATION DEVICE

(71) Applicant: Gigaphoton Inc., Tochigi (JP)

(72) Inventor: Tatsuya YANAGIDA, Oyama-shi (JP)

(73) Assignee: Gigaphoton Inc., Tochigi (JP)

(21) Appl. No.: 16/244,319

(22) Filed: Jan. 10, 2019

Related U.S. Application Data
(63) Continuation of application No. PCT/JP2016/073795, filed on Aug. 12, 2016.

(51) Int. Cl. H05G 2/00; G03F 7/20; H01S 3/00

(52) U.S. Cl. CPC H05G 2/003; H05G 2/008; H01S 3/005; G03F 7/70025; G03F 7/70033

(57) ABSTRACT

A droplet detector preferably includes: an application unit configured to emit a pulsed beam at a predetermined cycle and apply a plurality of pulsed beams to a droplet moving in a detection region on a trajectory; and a light receiving unit configured to receive a scattered pulsed beam that is generated from the plurality of pulsed beams applied to the droplet and scattered by the droplet.

### CROSS-REFERENCE TO RELATED APPLICATIONS

The present application is a continuation application of International Application No. PCT/JP2016/073795 filed on Aug. 12, 2016. The content of the application is incorporated herein by reference in its entirety.

### BACKGROUND

### 1. Technical Field

The present disclosure relates to a droplet detector and an extreme ultraviolet light generating apparatus.

### 2. Related Art

Nowadays, transfer patterns for use in photolithography in semiconductor processes are becoming finer and finer with semiconductor processes being moved to microfabrication. In next generation processes, fine patterning with a line width of 20 nm or less is to be requested. Thus, the development of exposure apparatuses is expected. These exposure apparatuses combine a device that generates extreme ultraviolet (EUV) light at a wavelength of about 13 nm with reduced projection reflective optics.

For extreme ultraviolet light generating apparatuses, three types of devices are proposed. The three types are: a laser produced plasma (LPP) device that uses plasma generated by applying a laser beam to a target substance; a discharge produced plasma (DPP) device that uses plasma generated by electric discharge; and a synchrotron radiation (SR) device that uses synchrotron orbital radiation.

### CITATION LIST

### Patent Literature

[Patent Literature 1] JP 2012-523694 A
[Patent Literature 2] WO 2013/161760 A
[Patent Literature 3] JP 2014-102258 A

### SUMMARY

A droplet detector according to one aspect of the present disclosure may include an application unit and a light receiving unit. The application unit may be configured to apply, to one droplet moving in a detection region, a plurality of pulsed beams at a predetermined cycle. The light receiving unit may be configured to receive a plurality of scattered pulsed beams, the plurality of scattered pulsed beams being generated by scattering, at the one droplet, the plurality of pulsed beams having been applied to the one droplet.

An extreme ultraviolet light generating apparatus according to one aspect of the present disclosure may include an application unit, a light receiving unit, a laser unit, and a controller. The application unit may be configured to apply, to one droplet moving in a detection region, a plurality of pulsed beams at a predetermined cycle. The light receiving unit may be configured to receive a plurality of scattered pulsed beams, the plurality of scattered pulsed beams being generated by scattering, at the one droplet, the plurality of pulsed beams having been applied to the one droplet. The laser unit may be configured to emit a pulsed laser beam. The controller may be configured to output, to the laser unit, a signal that gives a trigger to the laser unit to emit a pulsed laser beam in a manner that the pulsed laser beam is applied to the one droplet, when the one droplet detected in the detection region reaches a plasma generation region after received light intensity at the light receiving unit is changed.

### BRIEF DESCRIPTION OF THE DRAWINGS

In the following, some embodiments of the present disclosure will be described as simple examples with reference to the accompanying drawings.

FIG. 1 is a schematic diagram of an exemplifying configuration of an overall extreme ultraviolet light generating apparatus.

FIG. 2 is a schematic diagram of an exemplifying configuration of a part of an extreme ultraviolet light generating apparatus according to a comparative example.

FIG. 3 is a schematic diagram illustrating the projection of a droplet image to the light receiving surface of a light receiving unit.

FIGS. 4A-4C are a timing chart of a plurality of signals in the comparative example.

FIG. 5 is a schematic diagram of an exemplifying configuration of a part of an extreme ultraviolet light generating apparatus according to a first embodiment.

FIG. 6 is a schematic diagram of an exemplifying configuration of a droplet detector.

FIG. 7 is a schematic diagram of a pulse signal inputted from a photodetector to a controller.

FIG. 8 is a schematic diagram illustrating the generation of the envelope of a pulse signal inputted from the photodetector to the controller.

FIG. 9 is a schematic diagram illustrating the generation of a light emission trigger signal based on the envelope.

FIGS. 10A-10F are a timing chart of the processes for generating EUV light.

FIG. 11 is a schematic diagram of an exemplifying configuration of a droplet detector according to a second embodiment.

FIG. 12 is a schematic diagram of an exemplifying configuration of a part of an extreme ultraviolet light generating apparatus according to a third embodiment.

FIG. 13 is a schematic diagram of an exemplifying configuration of a droplet detector and a prepulse laser unit.

### DETAILED DESCRIPTION

1. Overview
2. Description of an Extreme Ultraviolet Light Generating Apparatus

2.1 Overall Configuration

2.2 Operation
3. Comparative Example

3.1 Configuration of a Part of an Extreme Ultraviolet Light Generating Apparatus

3.2 Operation

3.3 Problem
4. First Embodiment

4.1 Configuration of a Part of an Extreme Ultraviolet Light Generating Apparatus

4.2 Operation

4.3 Effect
5. Second Embodiment

5.1 Configuration of a Part of an Extreme Ultraviolet Light Generating Apparatus

5.2 Operation

5.3 Effect
6. Third Embodiment

6.1 Configuration of a Part of an Extreme Ultraviolet Light Generating Apparatus

6.2 Operation

6.3 Effect

In the following, embodiments of the present disclosure will be described in detail with reference to the drawings. The embodiments to be described below show some examples of the present disclosure, and do not limit the content of the present disclosure. All the configurations and the operations to be described in the embodiments are not necessarily required as the configurations and operations of the present disclosure.

The same components are designated the same reference signs, and redundant descriptions will be omitted.

### 1. OVERVIEW

Embodiments of the present disclosure relate to an extreme ultraviolet light generating apparatus that generates light with wavelengths referred to as extreme ultraviolet (EUV) light. Note that in the present specification below, the extreme ultraviolet light is sometimes referred to as EUV light.

### 2. DESCRIPTION OF AN EXTREME ULTRAVIOLET LIGHT GENERATING APPARATUS

2.1 Overall Configuration

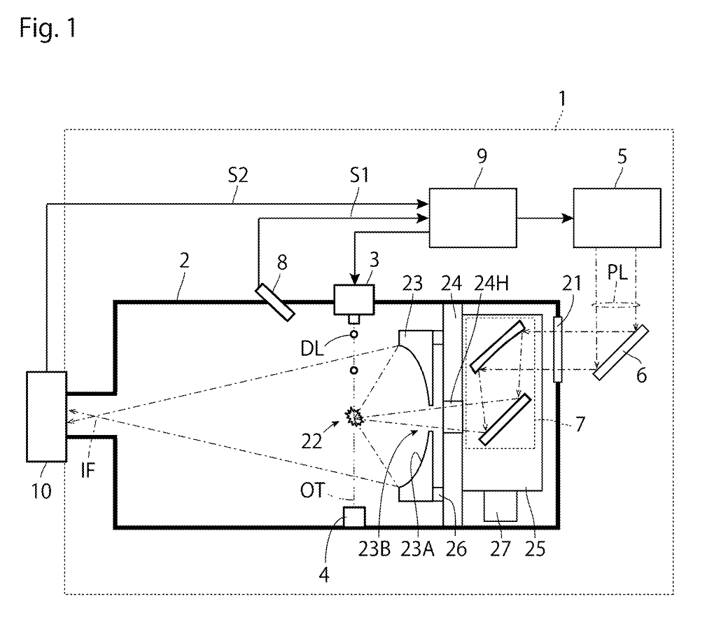

As illustrated in FIG. 1, an extreme ultraviolet light generating apparatus 1 according to this embodiment is used together with an exposure apparatus 10. The extreme ultraviolet light generating apparatus 1 includes a chamber 2, a target supply unit 3, a target collecting unit 4, a laser unit 5, a reflective mirror 6, a laser focusing optical system 7, a droplet detector 8, and a controller 9.

The chamber 2 is a sealable, pressure-reduceable container. On the wall of the chamber 2, at least one through hole is provided. The through hole is blocked with a window 21. The window 21 is configured to transmit a pulsed laser beam PL emitted from the laser unit 5 placed on the outside of the chamber 2.

At the inside of the chamber 2, a predetermined region on a trajectory OT of a droplet DL to be supplied to the inside of the chamber 2 is a plasma generation region in which the droplet DL is turned into plasma. The pulsed laser beam PL emitted from the laser unit 5 is focused on the plasma generation region 22.

At the inside of the chamber 2, a light collecting mirror 23 having a spheroidal reflection plane 23A is provided. The light collecting mirror 23 reflects EUV light included in light generated from the droplet DL, which has been turned into plasma in the plasma generation region 22, off the reflection plane 23A, focuses the EUV light on the focal point, and outputs the EUV light to the exposure apparatus 10. Note that the focal point may have a first focal point and a second focal point. For example, the first focal point is located in the plasma generation region 22. The second focal point is located at an intermediate focal point IF that is a focus position defined suitable for the specifications and the like of the exposure apparatus 10. The light collecting mirror 23 may include a through hole 23B in the center part of the reflection plane 23A, or may be placed in such a manner that the pulsed laser beam PL is passed through the through hole 23B.

At the inside of the chamber 2, a plate 24 and an optical system stage 25 are placed. The plate 24 is mounted on the chamber 2 so as, for example, to partition the inside of the chamber 2. The light collecting mirror 23 is fixed to one face of the plate 24 with a holder 26.

The optical system stage 25 is provided on the opposite side to the side, on which the light collecting mirror 23 is placed, with the plate 24 as the boundary. The position of the laser focusing optical system 7 placed on the mounting face of the optical system stage 25 can be moved by a stage moving mechanism 27.

The target supply unit 3 is configured to supply a target substance as the droplet DL to the inside of the chamber 2. The target supply unit 3 is mounted so as, for example, to penetrate through the wall of the chamber 2. The material of a target substance to be supplied from the target supply unit 3 may include, but is not limited to, any one of tin, terbium, gadolinium, lithium, and xenon or the combination of two or more of them.

The target collecting unit 4 is configured to collect droplets DL that are not turned into plasma in the plasma generation region 22 in the droplets DL having been supplied to the inside of the chamber 2. For example, the target collecting unit 4 is provided on the wall of the chamber 2 on the opposite side to the wall where the target supply unit 3 is mounted, and the target collecting unit 4 is provided on the trajectory OT of the droplet DL.

The laser unit 5 is configured to emit the pulsed laser beam PL that turns the droplets DL having been supplied to the inside of the chamber 2 into plasma. For example, the laser unit 5 may be a solid laser, such as a Nd:YAG laser and a Nd:YVO4 laser, or may emit the harmonic light of a solid laser. For example, the laser unit 5 may be a gas laser, such as a CO₂ laser and an excimer laser. For example, the laser unit 5 may emit a linearly polarized pulsed laser beam PL. The pulse duration may be a pico-second pulse duration that is 100 fS or more and less than 1 nS, or may be a nano-second pulse duration that is 1 nS or more.

The reflective mirror 6 is a mirror that reflects the pulsed laser beam PL emitted from the laser unit 5 at a high reflectance. For example, the reflective mirror 6 can be configured of a flat dielectric multi-layer film, a metal, and the like.

The laser focusing optical system 7 is an optical system that focuses the pulsed laser beam PL emitted from the laser unit 5 on the plasma generation region 22. The laser focusing optical system 7 according to the embodiment focuses the pulsed laser beam PL, which has been reflected off the reflective mirror 6 and guided to the inside of the chamber 2 through the window 21, on the plasma generation region 22 through a through hole 24H of the plate 24 and the through hole 23B of the light collecting mirror 23 using a plurality of mirrors. The focus position of the pulsed laser beam PL is changeable using the stage moving mechanism 27 of the optical system stage 25.

The droplet detector 8 is configured to detect the droplet DL moving in the detection region on the trajectory OT. The droplet detector 8 supplies, to the controller 9, a passage timing signal S1 indicating the timing at which the droplet DL is passing through the detection region. Note that the droplet detector 8 may be configured to detect the trajectory, speed, and the like of the droplet DL other than the passage timing of the droplet DL.

The controller 9 is configured to control the overall extreme ultraviolet light generating apparatus 1. The controller 9 receives at least an input of the passage timing signal S1 from the droplet detector 8 and an input of a burst signal S2 from the exposure apparatus 10.

The burst signal S2 is a signal that specifies a burst period for which EUV light has to be generated and an idle period for which the generation of EUV light has to be stopped. In the burst signal S2, the burst period and the idle period are repeated. The burst pattern is defined by data including any one or a plurality of the energy of EUV light, the repetition frequency, the number of pulses, the length of the burst period, the length of the idle period, and the number of bursts. The settings of the burst pattern are established in the exposure apparatus 10.

The controller 9 appropriately controls the laser unit 5 based on the passage timing signal S1 and the burst signal S2 in such a manner that the pulsed laser beam PL is applied when the droplet DL reaches the plasma generation region 22 in the burst period.

Note that the controller 9 may be configured to control the target supply unit 3 based on the detected result at the droplet detector 8 in such a manner that, for example, the output timing and the output direction of the droplet DL are adjusted. The controller 9 may be configured to control the laser focusing optical system 7 based on the detected result at the droplet detector 8 in such a manner that the pulsed laser beam PL is applied to a predetermined target position in the plasma generation region 22. These control methods are merely examples. The control methods may be replaced by other control methods, or may be additionally provided with another control method.

2.2 Operation

The controller 9 causes the laser unit 5 to emit the pulsed laser beam PL in the burst period. The pulsed laser beam PL emitted from the laser unit 5 is reflected off the reflective mirror 6, and propagates from the window 21 of the chamber 2 to the laser focusing optical system 7. The pulsed laser beam PL reaches the laser focusing optical system 7, and the laser focusing optical system 7 focuses the pulsed laser beam PL on the plasma generation region 22.

Here, the controller 9 controls the laser unit 5 to apply the pulsed laser beam PL when the droplet DL reaches the plasma generation region 22 in the burst period. Thus, the pulsed laser beam PL is applied to the droplet DL that has been supplied from the target supply unit 3 to the inside of the chamber 2 and has reached the plasma generation region 22.

The droplet DL, to which the pulsed laser beam PL has been applied, is turned into plasma, and light including EUV light is emitted from the plasma. The EUV light is selectively reflected off the reflection plane 23A of the light collecting mirror 23, and guided to the exposure apparatus 10 on the outside of the chamber 2.

### 3. COMPARATIVE EXAMPLE

3.1 Configuration of a Part of an Extreme Ultraviolet Light Generating Apparatus

Next, as a comparative example with embodiments below, the configuration of a part of an extreme ultraviolet light generating apparatus will be described. Note that configurations similar to the configurations described above are designated the same reference signs, and redundant descriptions will be omitted unless otherwise specified.

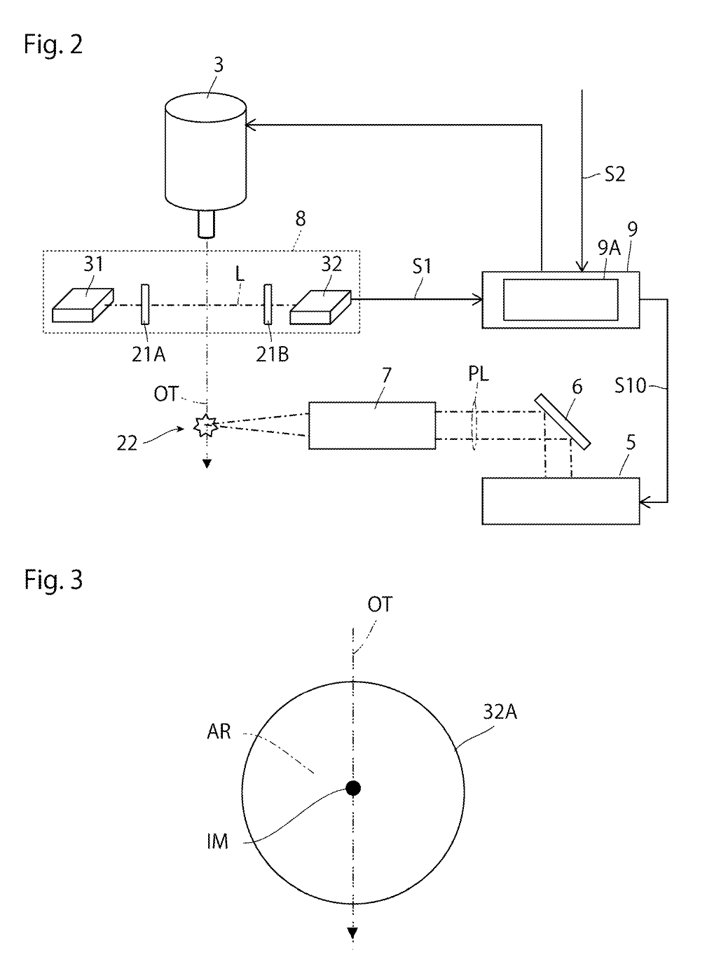

As illustrated in FIG. 2, a droplet detector 8 of an extreme ultraviolet light generating apparatus according to the comparative example is configured of an application unit 31 and a light receiving unit 32. The application unit 31 and the light receiving unit 32 are placed on a line nearly orthogonal to a trajectory OT of a droplet DL. Between the application unit 31 and the light receiving unit 32, a pair of windows 21A and 21B forming a part of the walls of a chamber 2 is provided. The windows 21A and 21B are configured to transmit light. Note that in FIG. 2, for convenience, the chamber 2 except the windows 21A and 21B and other components are partially omitted.

The application unit 31 is placed on the window 21A side on the outside of the chamber 2. The application unit 31 emits a CW laser beam L through the window 21A toward a predetermined detection region located on the target supply unit 3 side in the plasma generation region 22 on the trajectory OT of the droplet DL.

The light receiving unit 32 is placed on the window 21B side on the outside of the chamber 2. The light receiving unit 32 receives the CW laser beam L that enters from the window 21B after the beam L is emitted from the application unit 31 through the detection region on the trajectory OT of the droplet DL. The light receiving unit outputs a signal indicating the intensity of the received CW laser beam L as a passage timing signal S1 to the controller 9.

3.2 Operation

In the extreme ultraviolet light generating apparatus according to the comparative example, the CW laser beam L applied from the application unit 31 to the detection region on the trajectory OT of the droplet DL is received at the light receiving unit 32 placed on almost the same straight line on which the application unit 31 is located across the trajectory OT. The light receiving unit 32 generates the passage timing signal S1 indicating the received light intensity, and outputs the signal S1 to the controller 9.

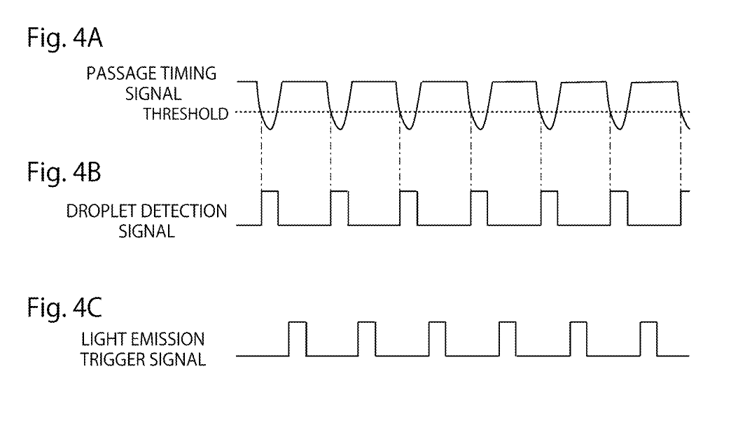

Here, in the case in which the droplet DL supplied from the target supply unit 3 to the inside of the chamber 2 is present in the detection region, as illustrated in FIG. 3, an image IM of the droplet DL is projected onto an application area AR of the CW laser beam L on a light receiving surface 32A of the light receiving unit 32. Thus, the amount of the received light intensity is decreased by the amount corresponding to the area of the image IM of the droplet DL. At this time, the received light intensity indicated by the passage timing signal S1 is below a predetermined threshold (FIG. 4A). The controller 9 recognizes that the droplet DL has reached the detection region based on the passage timing signal S1.

The controller 9 generates a droplet detection signal at a time point at which the received light intensity indicated by the passage timing signal S1 is below a predetermined threshold (FIG. 4B). The controller 9 delays the droplet detection signal by a predetermined delay time using a delay circuit 9A provided in its inside (FIG. 4C). The droplet detection signal thus delayed by the predetermined delay time is outputted as a light emission trigger signal S10 to the laser unit 5. The light emission trigger signal S10 is the signal that gives a trigger to the laser unit 5 to emit the pulsed laser beam PL.

Note that the delay time is a time period that a time period for which the pulsed laser beam PL emitted from the laser unit 5 reaches the plasma generation region 22 is subtracted from a time period for which the droplet DL present in the detection region for the CW laser beam L reaches the plasma generation region 22. Consequently, the pulsed laser beam PL emitted from the laser unit 5 is applied to the droplet DL that has reached the plasma generation region 22 from the detection region for the CW laser beam L.

3.3 Problem

Nowadays, there is a request to generate a smaller droplet DL. Generating EUV light with a droplet DL in a minimum necessary amount enables a reduction in the used amount of a target substance, and this enables prolonged operating time. In addition to this, contaminants generated in association with one-time plasma generation can be reduced. Thus, the operating time of the apparatus can be further improved. However, in the case in which the area of the image IM of the droplet DL projected onto the application area AR is decreased, there is a concern that the received light intensity indicated by the passage timing signal S1 is not below the threshold and no light emission trigger signal S10 is outputted from the controller 9 to the laser unit 5. In this case, there is a concern that even though the droplet DL that has to be originally turned into plasma reaches the plasma generation region 22, no pulsed laser beam PL is applied to the droplet DL, and no EUV light is generated.

Therefore, embodiments below describe an exemplifying droplet detector that can appropriately detect a droplet DL passing through the detection region and an exemplifying extreme ultraviolet light generating apparatus that can turn the droplet DL into plasma using the droplet detector.

### 4. FIRST EMBODIMENT

4.1 Configuration of a Part of an Extreme Ultraviolet Light Generating Apparatus

Next, as a first embodiment, the configuration of an extreme ultraviolet light generating apparatus will be described. Note that configurations similar to the configurations described above are designated the same reference signs, and redundant descriptions will be omitted unless otherwise specified.

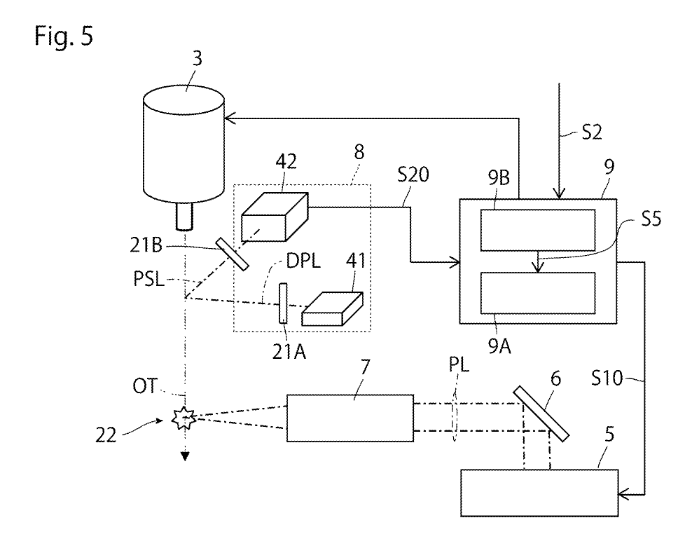

As illustrated in FIG. 5, a droplet detector 8 of the extreme ultraviolet light generating apparatus according to the first embodiment is configured of an application unit 41 and a light receiving unit 42. The application unit 41 and the light receiving unit 42 are placed in a plane orthogonal to a trajectory OT of a droplet DL and placed at positions different from the positions facing to each other across the trajectory.

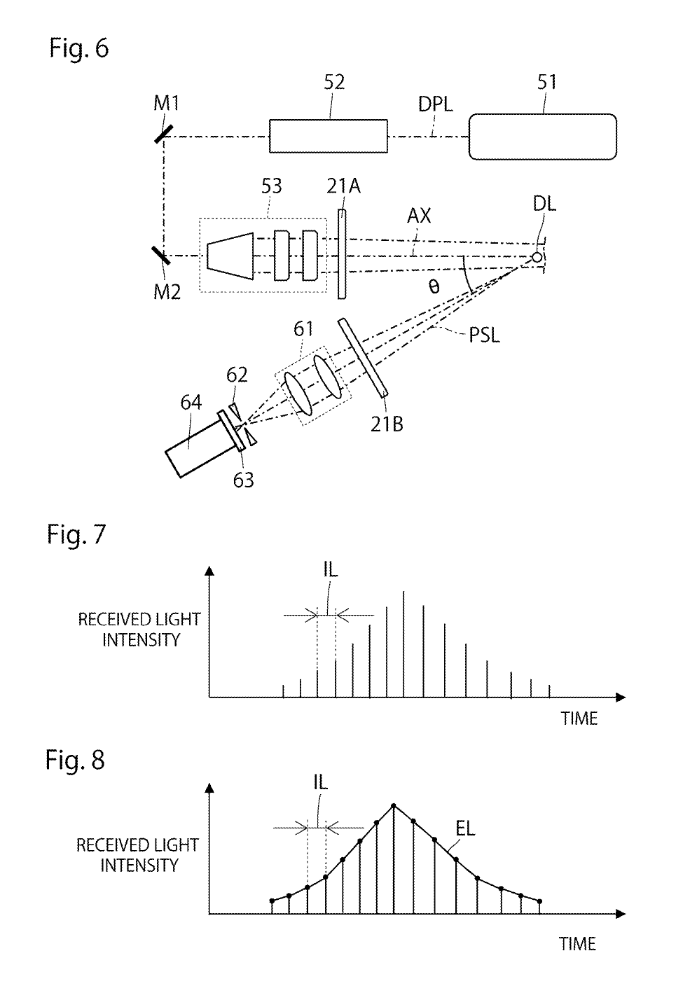

The application unit 41 emits a detection pulsed beam DPL in a predetermined cycle, and applies, through a window 21A, a plurality of pulsed beams DPL to the droplet DL moving in the detection region on the trajectory OT. For example, as illustrated in FIG. 6, the application unit 41 includes a mode-locked laser 51, a wavelength converting unit 52, and an illuminating optical system 53.

The mode-locked laser 51 is a laser that generates the pulsed beam DPL having a short pulse duration in a predetermined cycle by synchronizing a phase in longitudinal mode in a laser oscillator. The mode-locked laser 51 is configured of, for example, a laser medium, a saturable absorber mirror, and a partially reflective mirror. The pulse interval of the pulsed beam DPL emitted from the mode-locked laser 51 is a time period that a doubled resonator length is divided by the velocity of light. Typically, the intensity of the pulsed beam DPL emitted from the mode-locked laser 51 is considerably higher than the intensity of a CW laser beam emitted from, for example, a He—Ne laser.

The wavelength converting unit 52 is configured to convert the wavelength of the pulsed beam DPL emitted from the mode-locked laser 51. The wavelength converting unit is configured of, for example, a bulk crystal. The wavelength converted at the wavelength converting unit 52 may be the second harmonic or other wavelengths. In the case in which the mode-locked laser 51 is a Nd:YVO4 laser, the wavelength of the pulsed beam DPL emitted from the mode-locked laser 51 is 1,064 nm, and the second harmonic is 532 nm. Note that the wavelength converting unit 52 may be omitted.

The illuminating optical system 53 is configured to shape the pulsed beam emitted from the mode-locked laser 51 in a sheet-like pulse beam in the detection region on the trajectory OT, having a configuration using, for example, a cylindrical lens.

Note that the pulsed beam DPL propagating from the mode-locked laser 51 through the wavelength converting unit is transmitted to the illuminating optical system 53 using two mirrors M1 and M2. However, the pulsed beam DPL may be transmitted using an optical fiber instead of the mirrors M1 and M2.

After the application of the pulsed beam DPL to the droplet DL moving in the detection region on the trajectory OT generates a scattered pulsed beam PSL that is a pulsed beam scattered from the droplet DL, the light receiving unit 42 receives the scattered pulsed beam PSL. For example, as illustrated in FIG. 6, the light receiving unit includes a light receiving optical system 61 and a photodetector 64.

The light receiving optical system 61, having a configuration using a light collecting lens, is configured to guide the scattered pulsed beams PSL scattered from the droplet DL present in the detection region to the photodetector 64. Note that a visual field restriction aperture 62 that passes only the scattered pulsed beams PSL scattered from the droplet DL present in the detection region may be used, or an optical filter 63 that selectively propagates the wavelength of the pulsed beam DPL emitted from the mode-locked laser 51 may be used.

The photodetector 64 receives the scattered pulsed beam PSL guided from the light receiving optical system 61, subjects the scattered pulsed beam PSL to photoelectric conversion, and outputs a pulse signal S20 indicating the received light intensity of the scattered pulsed beam PSL to a controller 9 (FIG. 5).

Note that an angle θ formed between the application unit 41 and the light receiving unit 42 placed in a plane orthogonal to the trajectory OT of the droplet DL is zero degrees or more and less than 180 degrees. The intensity of the scattered pulsed beams PSL scattered from the droplet DL present in the detection region is the largest in the direction coaxial with an optical axis AX of the pulsed beam DPL. The intensity of the scattered pulsed beam PSL is smaller as the scattered pulsed beam PSL is more apart from the optical axis AX of the pulsed beam DPL applied from the application unit 41. Consequently, from the viewpoint of increasing the received light intensity of the scattered pulsed beam PSL, the angle θ formed between the application unit 41 and the light receiving unit 42 placed in the plane orthogonal to the trajectory OT of the droplet DL is preferably zero degrees or more and less than 30 degrees.

The controller 9 (FIG. 5) has a delay circuit 9A and a trigger generating unit 9B. To the trigger generating unit 9B, the pulse signal S20 is inputted from the photodetector 62. As illustrated in FIG. 7, the pulse signal S20 is inputted at an interval IL corresponding to the cycle of the mode-locked laser 51. The strength of the pulse signal S20 exhibits the state in which the center is high and both sides are low due to the relationship between the droplet DL moving in the detection region and the optical axis AX of the pulsed beam DPL applied to the detection region.

As illustrated in FIG. 8, the trigger generating unit 9B detects an envelope EL based on the received light intensity of the pulse signal S20 inputted at the interval IL corresponding to the cycle of the mode-locked laser 51, and detects a value as a threshold at a predetermined ratio to the largest received light intensity based on the envelope EL. The ratio is, for example, 1/2.

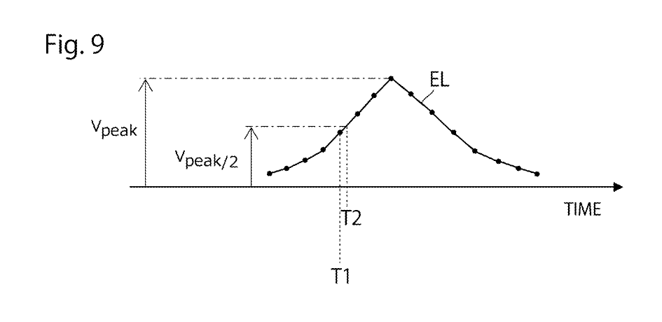

In the case in which the threshold is determined as illustrated in FIG. 9, the trigger generating unit 9B generates a droplet detection signal S5 at a detection timing T1 of the pulse signal S20 closest to a time point T2 at which the envelope EL exceeds the threshold, and outputs the droplet detection signal S5 to the delay circuit 9A.

As described above, the trigger generating unit 9B generates the droplet detection signal S5 at the detection timing T1 of the pulse signal S20 closest to the time point T2 at which the envelope EL exceeds the threshold. Thus, the droplet detection signal S5 is synchronized with the interval IL corresponding to the cycle of the mode-locked laser 51. Note that the droplet detection signal S5 may be generated at the time point T2 at which the envelope EL exceeds the threshold.

The delay circuit 9A generates the light emission trigger signal S10 by delaying the droplet detection signal S5 supplied from the trigger generating unit 9B by a predetermined delay time, and outputs the light emission trigger signal S10 to the laser unit 5.

4.2 Operation

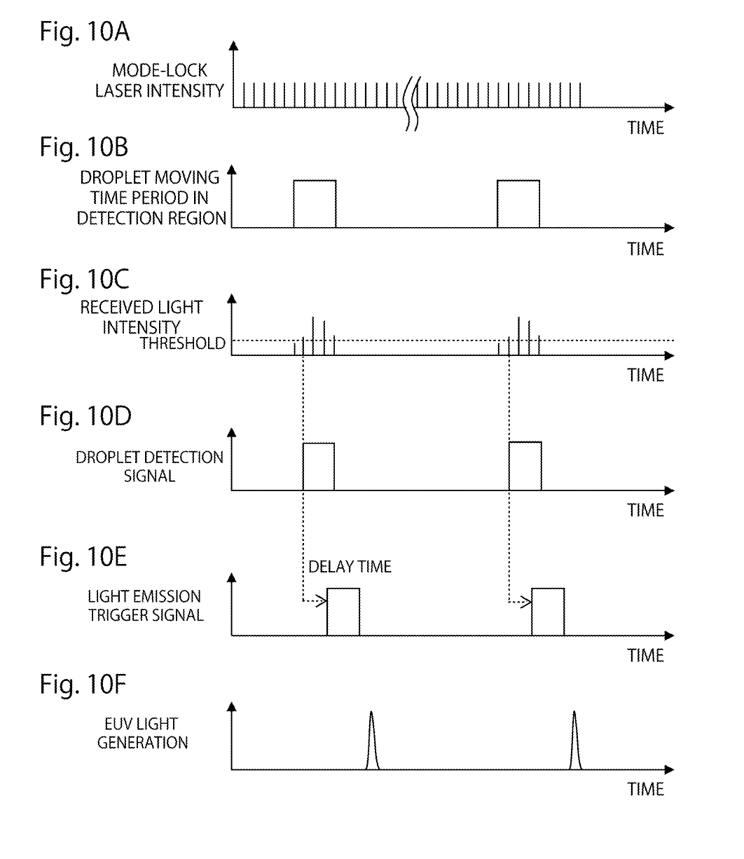

The mode-locked laser 51 emits the pulsed beam DPL at a cycle of, for example, 10 ns (FIG. 10A). The target supply unit 3 supplies the droplet DL to the inside of the chamber 2 at an interval of, for example, 10 μs. Thus, in a moving period for which the droplet DL is moving in the detection region on the trajectory OT (FIG. 10B), a plurality of pulsed beams DPL is applied to the droplet DL. With this application, the scattered light scattered from the droplet DL is subjected to photoelectric conversion at the photodetector 62 through the light receiving optical system 61 of the light receiving unit 42, and the pulse signal S20 is generated at the interval IL corresponding to the cycle of the mode-locked laser 51 (FIG. 10C).

The pulse signal S20 is outputted to the controller 9, and the droplet detection signal S5 is generated at the time point T1 at which the pulse signal S20 indicating the received light intensity close to the threshold detected at the trigger generating unit 9B of the controller 9 is inputted (FIG. 10D). After the generation, the light emission trigger signal S10 is generated by delaying the droplet detection signal S5 by a predetermined delay time at the delay circuit 9A of the controller 9, and the light emission trigger signal S10 is outputted to the laser unit (FIG. 10E). Consequently, the pulsed laser beam PL emitted from the laser unit 5 based on the light emission trigger signal S10 is applied to the droplet DL that has moved from the detection region on the trajectory OT to the plasma generation region 22, the droplet DL is turned into plasma, and EUV light is generated (FIG. 10F).

4.3 Effect

The droplet detector 8 of the extreme ultraviolet light generating apparatus according to the embodiment includes the application unit 41 configured to emit a high luminance pulsed beam DPL from the mode-locked laser 51 at a predetermined cycle and apply a plurality of high luminance pulsed beams DPL to the droplet DL moving in the detection region on the trajectory OT. The droplet detector 8 includes the light receiving unit 42 configured to receive the scattered pulsed beams PSL scattered from the droplet DL by applying the high luminance pulsed beams DPL to the droplet DL moving in the detection region.

Since the pulsed beam DPL generated at the mode-locked laser 51 is of high intensity, the signal-to-noise (SN) ratio of the signal outputted from the light receiving unit 42 as the received result at the light receiving unit 42 can be improved. Therefore, in the droplet detector 8, a plurality of high luminance scattered pulsed beams PSL scattered from the droplet DL moving in the detection region is received. Thus, even in the case in which the droplet DL is small, the received light intensity at the light receiving unit 42 is not prone to be below the detection threshold.

Since the scattered pulsed beam PSL is received, the influence of the displacement between the optical axes of the application unit 41 and the light receiving unit 42 is small, compared with the case in which the image of the detection region is projected onto the light receiving surface of the light receiving unit using the CW laser beam applied from the application unit. Consequently, the droplet detector 8 can appropriately detect the droplet DL passing through the detection region.

In the droplet detector 8, a plurality of pulsed beams DPL is applied to the droplet DL moving in the detection region, and the scattered pulsed beams PSL scattered from the droplet DL by the application are received. Thus, even in the case in which a part of the intensity of the scattered pulsed beams PSL is weakened or a part of the scattered pulsed beams PSL fails to be received, the droplet DL passing through the detection region can be detected from the received result of the other scattered pulsed beams PSL.

The application unit 41 and the light receiving unit according to the embodiment are placed in the plane orthogonal to the trajectory OT and placed at positions different from the positions facing to each other across the trajectory OT. Thus, the degree of freedom of placing the application unit 41 and the light receiving unit 42 can be improved, compared with the case in which the application unit and the light receiving unit are placed at the positions facing to each other across the trajectory OT.

### 5. SECOND EMBODIMENT

5.1 Configuration of a Part of an Extreme Ultraviolet Light Generating Apparatus

Next, as a second embodiment, the configuration of a part of an extreme ultraviolet light generating apparatus will be described. Note that configurations similar to the configurations described above are designated the same reference signs, and redundant descriptions will be omitted unless otherwise specified.

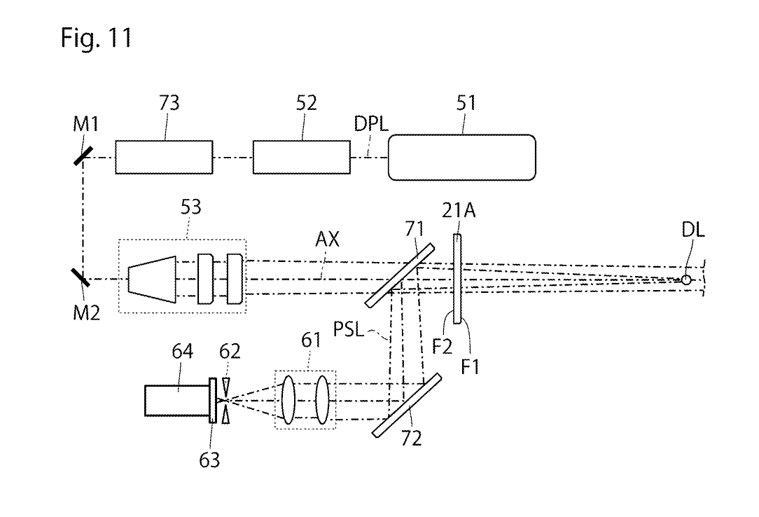

As illustrated in FIG. 11, in a droplet detector 8 of the extreme ultraviolet light generating apparatus according to the second embodiment, a beam splitter 71, a reflective mirror 72, and an optical isolator 73 are included, in addition to the components of the first embodiment.

The beam splitter 71 is placed between an illuminating optical system 53 and a window 21A. The beam splitter 71 transmits a part of a detection pulsed beam DPL going from the illuminating optical system 53 to the window 21A along the optical axis AX. The beam splitter 71 reflects a part of scattered light going to the illuminating optical system 53 through the window 21A along the optical axis AX in the scattered light scattered from a droplet DL present in the detection region on a trajectory OT. The reflectance of the beam splitter 71 may be 50%, for example.

The reflective mirror 72 is placed between the beam splitter 71 and a light receiving optical system 61. The reflective mirror 72 reflects the scattered light having been reflected off the beam splitter 71, and guides the scattered light to the light receiving optical system 61.

The optical isolator 73 is placed on the optical path between the beam splitter 71 and a mode-locked laser 51, such as at a location between a mirror M1 and a wavelength converting unit 52. The optical isolator 73 reduces the scattered light that returns from the beam splitter 71 to the mode-locked laser 51.

Note that in order to reduce the scattered light returning to the mode-locked laser 51, a face F1 of the window 21A, to which scattered light enters, may be tilted to an optical axis AX of the pulsed beam DPL applied from an application unit 41. In the case of reducing the scattered light returning to the mode-locked laser 51 using a component other than the optical isolator 73 as described above, the optical isolator 73 may be omitted.

In order to prevent the pulsed beam DPL applied from the application unit 41 from being reflected off the window 21A, an antireflection film may be provided on a face F2 of the window 21A, to which the pulsed beam DPL enters.

5.2 Operation

The pulsed beam DPL emitted from the mode-locked laser 51 goes to the beam splitter 71, in turn passing through the wavelength converting unit 52, the optical isolator 73, the mirrors M1 and M2, and the illuminating optical system 53. A part of the pulsed beam DPL is transmitted through the beam splitter 71, and applied to the detection region on the trajectory OT of the droplet DL through the window 21A.

Here, after the droplet DL supplied from the target supply unit 3 to the inside of the chamber 2 moves to the detection region and the pulsed beam DPL is applied to the droplet DL, scattered light is generated from the droplet DL. In the scattered light, scattered light propagating in the direction of the optical axis AX of the pulsed beam DPL reaches the beam splitter 71 through the window 21A, and a part of the scattered light having reached the beam splitter 71 is reflected off the beam splitter 71. The reflected scattered light is entered to a photodetector 62 in turn through the reflective mirror 72 and the light receiving optical system 61.

5.3 Effect

In the droplet detector 8 of the extreme ultraviolet light generating apparatus according to the embodiment, the beam splitter 71 is placed on the optical axis AX of the pulsed beam DPL emitted from the mode-locked laser 51, and this makes the optical axis of the light receiving unit 42 coaxial with the optical axis AX. Thus, even in the case in which the application unit 41 and the light receiving unit 42 are placed in the state in which the angle θ formed between the application unit 41 and the light receiving unit 42 placed in the plane orthogonal to the trajectory OT of the droplet DL is not zero degrees, the scattered light having the largest intensity can be received. Consequently, in the droplet detector 8 according to the embodiment, even when the restriction is imposed on the placement of the application unit 41 or the light receiving unit 42, the droplet DL passing through the detection region can be appropriately detected. In addition to this, in the droplet detector 8 according to the embodiment, the optical axis of the light receiving unit 42 is coaxial with the optical axis AX of the pulsed beam DPL emitted from the mode-locked laser 51, and this enables the omission of a window 21B.

Note that the intensity of the pulsed beam DPL is decreased because the beam splitter 71 is placed on the optical axis AX of the pulsed beam DPL. However, the intensity of the scattered light scattered from the droplet DL to the beam splitter 71 is strong enough, compared with scattered light going to the other directions. Thus, the SN ratio is sufficiently held.

In the droplet detector 8 according to the embodiment, the beam splitter 71 is placed on the optical axis AX of the pulsed beam DPL emitted from the mode-locked laser 51 on the downstream side from the illuminating optical system 53, which is on the opposite side to the upstream side where the mode-locked laser 51 is placed. However, the beam splitter 71 may be placed upstream of the illuminating optical system 53. In the case in which the beam splitter 71 is placed upstream of the illuminating optical system 53, the droplet detector 8 can share the illuminating optical system 53 of the application unit 41 with the light receiving optical system 61 of the light receiving unit 42. Thus, this enables a reduction in the number of parts of the droplet detector 8.

### 6. THIRD EMBODIMENT

6.1 Configuration of a Part of an Extreme Ultraviolet Light Generating Apparatus

Next, as a third embodiment, the configuration of a part of an extreme ultraviolet light generating apparatus will be described. Note that configurations similar to the configurations described above are designated the same reference signs, and redundant descriptions will be omitted unless otherwise specified.

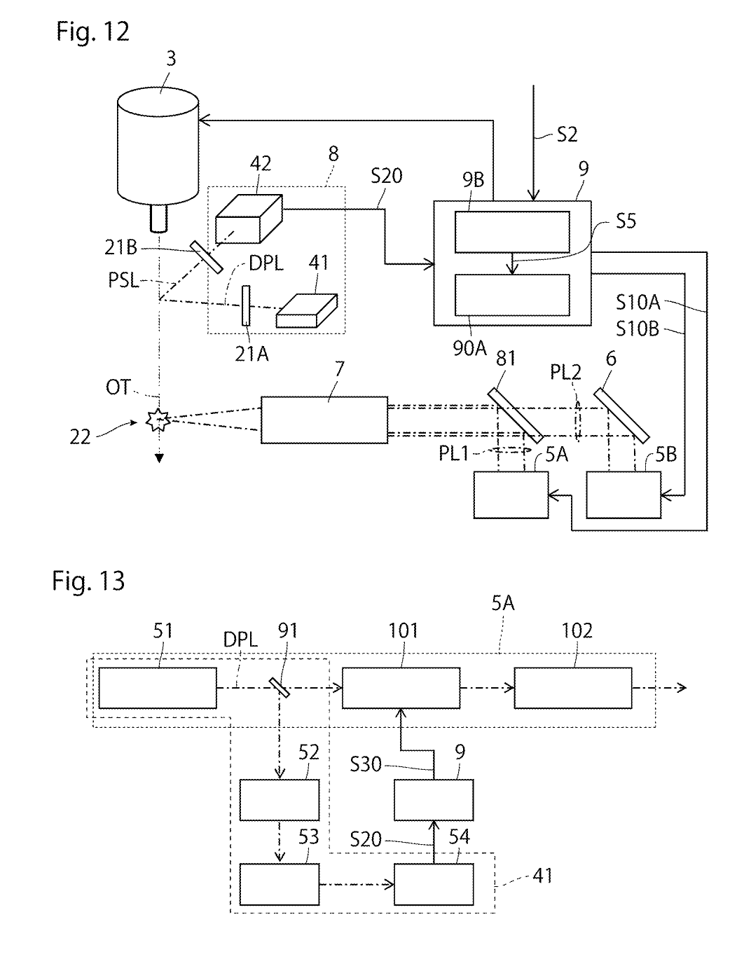

As illustrated in FIG. 12, in the extreme ultraviolet light generating apparatus according to the third embodiment, the laser unit 5 according to the first embodiment is configured of a prepulse laser unit 5A and a main pulse laser unit 5B. In the extreme ultraviolet light generating apparatus according to the third embodiment, a beam combiner 81 is newly provided, and the delay circuit 9A of the controller 9 according to the first embodiment is changed to a delay circuit 90A.

The prepulse laser unit 5A is configured to emit a prepulsed laser beam PL1 to disperse a droplet DL supplied to the inside of a chamber 2. Examples of the prepulse laser unit 5A that are applicable include lasers described as examples of the laser unit 5 in the first embodiment.

The main pulse laser unit 5B is configured to emit a main pulsed laser beam PL2 to turn the dispersed droplet DL into plasma. Examples of the main pulse laser unit 5B that are applicable include lasers described as examples of the laser unit 5 in the first embodiment.

Note that pulse energy and pulse duration are individually set to the prepulse laser unit 5A and the main pulse laser unit 5B, and these settings adjust the fluence (mJ/cm²) and the light intensity (W/m²) of the prepulsed laser beam PL1 and the main pulsed laser beam PL2 individually to the droplet DL.

The beam combiner 81 is placed so as to approximately align the optical path axis of the prepulsed laser beam PL1 with the optical path axis of the main pulsed laser beam PL2. For example, the beam combiner 81 is configured to transmit the main pulsed laser beam PL2 reflected off the reflective mirror 6 and to reflect the prepulsed laser beam PL1 in such a manner that the optical path axis of the prepulsed laser beam PL1 emitted from the prepulse laser unit 5A is approximately aligned with the optical path axis of the main pulsed laser beam PL2.

The delay circuit 90A of the controller 9 delays the droplet detection signal S5 supplied from the trigger generating unit 9B by first delay time, and outputs the signal S5 as a first light emission trigger signal S10A to the prepulse laser unit 5A. The first delay time is a time period that a time period for which the prepulsed laser beam PL1 emitted from the prepulse laser unit 5A reaches the plasma generation region 22 is subtracted from a time period for which the droplet DL present in the detection region reaches the plasma generation region 22. The delay circuit 90A delays the droplet detection signal S5 by second delay time, and outputs the signal S5 as a second light emission trigger signal S10B to the main pulse laser unit 5B. The second delay time is a time period slightly longer than the first delay time.

In the extreme ultraviolet light generating apparatus according to the third embodiment, the prepulse laser unit 5A is configured to generate the prepulsed laser beam PL1 using a mode-locked laser 51 of a droplet detector 8 as a seed light source.

For example, as illustrated in FIG. 13, the prepulse laser unit 5A is configured of a mode-locked laser 51 shared by an application unit 41, a pulse pick 101, and a pulse amplifier 102.

The pulse pick 101 is an optical device that opens or closes the transmission line of a pulsed beam DPL emitted from the mode-locked laser 51. For example, the pulse pick 101 can be configured of an electrooptic (EO) device, a polarizer, and the like. The pulse pick 101 opens or closes the transmission line of a laser beam in such a manner that a laser beam at a repetition frequency of, for example, about 20 to 100 kHz in synchronization with the first light emission trigger signal S10A supplied from the controller 9 is outputted. The pulse amplifier 102 is configured to amplify the laser beam outputted from the pulse pick 101. The pulse amplifier 102 can be configured of, for example, a power amplifier that is a regenerative amplifier type.

As described above using FIG. 9, in the case in which the droplet detection signal S5 is generated at the detection timing T1 of the pulse signal S20 closest to the time point T2 at which the envelope EL exceeds the threshold, the light emission trigger signal S10 in synchronization with the interval IL corresponding to the cycle of the mode-locked laser 51 is generated. In contrast to this, in the case in which the droplet detection signal S5 is generated at the time point T2 at which the envelope EL exceeds the threshold, the light emission trigger signal S10 sometimes fails to be synchronized with the interval IL corresponding to the cycle of the mode-locked laser 51. In this case, the controller 9, for example, may be provided with a circuit and the like that adjust the opening and closing timing of the pulse pick 101 so as to selectively pass a pulse immediately after the light emission trigger signal S10 is inputted.

The droplet detection signal S5 may be generated at a time point at which the received light intensity is the largest in the envelope EL. In this case, a light emission trigger signal, generated including the delay time that is added to a time point at which the received light intensity is the largest in the envelope EL, may be outputted to the pulse pick 101. Also with this configuration, the opening and closing timing of the pulse pick 101 can be synchronized with the pulse timing of the mode-locked laser 51.

6.2 Operation

The first light emission trigger signal S10A is outputted to the prepulse laser unit 5A, and the second light emission trigger signal S10B is outputted to the main pulse laser unit 5B. In this case, in the burst period of the burst signal S2, the prepulsed laser beam PL1 and the main pulsed laser beam PL2 are alternately emitted in one pulse unit.

The prepulsed laser beam PL1 emitted from the prepulse laser unit 5A is reflected off the beam combiner 81. The prepulsed laser beam PL1 reflected off the beam combiner 81 goes to the plasma generation region 22 at the inside of the chamber 2 through a laser focusing optical system 7.

Here, the first light emission trigger signal S10A is delayed by a time period that a time period for which the prepulsed laser beam PL1 emitted from the prepulse laser unit 5A reaches the plasma generation region 22 is subtracted from a time period for which the droplet DL present in the detection region reaches the plasma generation region 22. Thus, when the droplet DL present in the detection region reaches the plasma generation region 22, the prepulsed laser beam PL1 is applied to the droplet DL, and the droplet DL is dispersed, and turned into a dispersed target substance.

On the other hand, the main pulsed laser beam PL2 emitted from the main pulse laser unit 5B and reflected off the reflective mirror 6 is transmitted through the beam combiner 81. The main pulsed laser beam PL2 transmitted through the beam combiner 81 goes to the plasma generation region 22 through the laser focusing optical system 7.

Here, the second light emission trigger signal S10B is delayed by a time period slightly longer than the delay time set to the first light emission trigger signal S10A. Thus, after the droplet DL present in the detection region reaches the plasma generation region 22 and the droplet DL is dispersed by the prepulsed laser beam PL1, the main pulsed laser beam PL2 is applied to the dispersed target substance. The dispersed target substance applied with the main pulsed laser beam PL2 is turned into plasma, and light including EUV light is emitted from the plasma.

Note that the delay time to apply the prepulsed laser beam PL1 and the main pulsed laser beam PL2, the fluence, the pulse duration, and the pulse waveform, for example, are adjusted, and this enables the improvement of conversion efficiency (CE) of laser beam energy into EUV light energy. The pulse duration of the prepulsed laser beam PL1 is shorter than the pulse duration of the main pulsed laser beam PL2, and this enables the improvement of conversion efficiency (CE) of laser beam energy into EUV light energy.

6.3 Effect

In the extreme ultraviolet light generating apparatus according to the embodiment, the laser unit 5 has the prepulse laser unit 5A configured to emit the prepulsed laser beam PL1 and the main pulse laser unit 5B configured to emit the main pulsed laser beam PL2. The prepulse laser unit 5A generates the prepulsed laser beam PL1 using the mode-locked laser 51 as a seed light source.

Thus, the mode-locked laser 51 is shared by the prepulse laser unit 5A and the application unit 41 of the droplet detector 8, and this enables a reduction in size of the extreme ultraviolet light generating apparatus by the shared mode-locked laser 51. The first light emission trigger signal S10A in synchronization with the pulse timing of the prepulse laser unit 5A can be generated.

The description above is merely examples, not limitation. Thus, it is apparent to a person skilled in the art that the embodiments of the present disclosure can be modified and altered without deviating from the scope of the appended claims.

The terms used throughout the specification and the appended claims should be interpreted as “non-limiting” terms. For example, the term “to include” or “to be included” should be interpreted to “include non-limiting components”. The term “to have” should be interpreted to “have non-limiting components”. The indefinite articles “a” and “an” described in the specification and the appended claims should be interpreted as meaning “at least one” or “one or more”.

What is claimed is:

1. A droplet detector comprising:
an application unit configured to apply, to one droplet moving in a detection region, a plurality of pulsed beams at a predetermined cycle; and
a light receiving unit configured to receive a plurality of scattered pulsed beams, the plurality of scattered pulsed beams being generated by scattering, at the one droplet, the plurality of pulsed beams having been applied to the one droplet.

2. The droplet detector according to claim 1, wherein
the application unit and the light receiving unit are placed in a plane orthogonal to a trajectory of the one droplet and placed at positions different from positions facing to each other across the trajectory.

3. The droplet detector according to claim 1, comprising
a beam splitter configured to transmit the pulsed beam applied from the application unit and reflect the scattered pulsed beam propagating toward an optical axis of the pulsed beam applied from the application unit, in the scattered pulsed beam scattered from the droplet moving in the detection region, wherein
the light receiving unit receives a scattered pulsed beam reflected off the beam splitter.

4. The droplet detector according to claim 1, wherein
the application unit includes
a mode-locked laser, and
an illuminating optical system configured to shape a pulsed beam emitted from the mode-locked laser in a manner that the pulsed beam is shaped in a sheet-like pulse beam in the detection region.

5. The droplet detector according to claim 1, wherein
the light receiving unit includes
a photodetector configured to subject the scattered pulsed beam to photoelectric conversion, and
a light receiving optical system configured to guide the scattered pulsed beam to the photodetector.

6. An extreme ultraviolet light generating apparatus comprising:
an application unit configured to apply, to one droplet moving in a detection region, a plurality of pulsed beams at a predetermined cycle;
a light receiving unit configured to receive a plurality of scattered pulsed beams, the plurality of scattered pulsed beams being generated by scattering, at the one droplet, the plurality of pulsed beams having been applied to the one droplet;
a laser unit configured to emit a pulsed laser beam; and
a controller configured to output, to the laser unit, a signal that gives a trigger to the laser unit to emit a pulsed laser beam in a manner that the pulsed laser beam is applied to the one droplet, when the one droplet detected in the detection region reaches a plasma generation region after received light intensity at the light receiving unit is changed.

7. The extreme ultraviolet light generating apparatus according to claim 6, wherein
the controller detects a value at a predetermined ratio to largest received light intensity at an interval corresponding to a period of a mode-locked laser included in the application unit, based on an envelope of received light intensity indicated by a plurality of pulse signals inputted from the light receiving unit, and
the controller delays a signal generated based on a pulse signal closest to a time point at which the envelope exceeds the value by a predetermined period to form a signal that gives a trigger to emit the pulsed laser beam to the one droplet.

8. The extreme ultraviolet light generating apparatus according to claim 6, wherein
the application unit includes
a mode-locked laser, and
an illuminating optical system configured to shape a pulsed beam emitted from the mode-locked laser in a manner that the pulsed beam is shaped in a sheet-like pulse beam in the detection region,
the laser unit includes
a prepulse laser unit configured to apply a prepulsed laser beam, and
a main pulse laser unit configured to apply a main pulsed laser beam, and
the prepulse laser unit generates the prepulsed laser beam using the mode-locked laser as a seed light source.

9. The extreme ultraviolet light generating apparatus according to claim 6, further comprising
a target supply unit configured to output the one droplet, wherein
the application unit is placed in a manner that the detection region is located on the target supply unit side of the plasma generation region.

10. An extreme ultraviolet light generating apparatus comprising:
an application unit configured to apply, to one droplet moving in a detection region, a plurality of pulsed beams outputted from a mode-locked laser at a predetermined cycle;
a light receiving unit configured to receive a plurality of scattered pulsed beams generated by scattering, at the one droplet, the plurality of pulsed beams having been applied to the one droplet;
a prepulse laser unit configured to emit a prepulsed laser beam using the pulsed beam as seed light; and
a controller configured to output a signal that gives a trigger to the prepulse laser unit to emit the prepulsed laser beam in a manner that the prepulsed laser beam is applied to the one droplet when the one droplet detected in the detection region reaches a plasma generation region after received light intensity at the light receiving unit is changed.

11. The extreme ultraviolet light generating apparatus according to claim 10, wherein
the application unit includes an illuminating optical system configured to shape a pulsed beam emitted from the mode-locked laser in a manner that the pulsed beam is shaped in a sheet-like pulse beam in the detection region.

12. The extreme ultraviolet light generating apparatus according to claim 10, further comprising
a main pulse laser unit configured to emit a main pulsed laser beam, wherein
the controller outputs a signal that gives a trigger to the main pulse laser unit to emit the main pulsed laser beam in a manner that the main pulsed laser beam is applied to a dispersed target substance dispersed from the one droplet to which the prepulsed laser beam has been applied.

13. The extreme ultraviolet light generating apparatus according to claim 10, further comprising
a target supply unit configured to output the one droplet, wherein
the application unit is placed in a manner that the detection region is located on the target supply unit side of the plasma generation region.
